(19) United States
(12) Patent Application Publication
(10) Pub. No.: US 2022/0328236 A1
(43) Pub. Date: Oct. 13, 2022

(54) RADIO FREQUENCY DISTRIBUTION CIRCUITS INCLUDING TRANSFORMERS AND/OR TRANSFORMER COUPLED COMBINERS

(71) Applicant: Lam Research Corporation, Fremont, CA (US)

(72) Inventor: Sunil Kapoor, Vancouver, WA (US)

(73) Assignee: Lam Research Corporation, Fremont, CA (US)

(21) Appl. No.: 17/754,202

(22) PCT Filed: Sep. 28, 2020
(86) PCT No.: PCT/US2020/053014

§ 371 Date: Mar. 25, 2022

Related U.S. Application Data
(60) Provisional application No. 62/908,846, filed on Oct. 1, 2019.

(51) Int. Cl. H01F 27/28

(52) U.S. Cl. CPC H01F 27/2823; H01F 27/288; H01F 2027/2833

(57) ABSTRACT

A transformer includes a primary coil and a secondary coil. The primary coil includes: a first shield of a first coaxial cable; a second shield of a second coaxial cable; and a conductive interconnector connecting the first shield to the second shield. The secondary coil includes: a first core of the first coaxial cable; a second core of the second coaxial cable; and a pair of conductive lines connecting the first core to the second core.

### CROSS-REFERENCE TO RELATED APPLICATIONS

This application claims the benefit of U.S. Provisional Application No. 62/908,846, filed on Oct. 1, 2019. The entire disclosure of the application referenced above is incorporated herein by reference.

### FIELD

The present disclosure relates to apparatuses for the manufacture and treatment of semiconductor and solid state devices, and more particularly to radio frequency (RF) distribution circuits of substrate processing systems.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems may be used to treat substrates such as semiconductor wafers. Examples of substrate treatments include etching, deposition, etc. During processing, the substrate is arranged on a substrate support such as an electrostatic chuck (ESC) and one or more process gases may be introduced into the processing chamber.

The one or more process gases may be delivered by a gas delivery system to the processing chamber. In some systems, the gas delivery system includes a manifold connected to a showerhead that is located in the processing chamber. As an example, during an etching process, a substrate may be arranged on an ESC in a substrate processing system and a thin film on the substrate is etched. As another example, a thin film is deposited on a substrate using atomic layer deposition (ALD). During the processing of a substrate one or more RF signals may be supplied to an electrode of the showerhead to adjust plasma ionization density and ionization energy.

### SUMMARY

A transformer is provided and includes a primary coil and a secondary coil. The primary coil includes: a first shield of a first coaxial cable; a second shield of a second coaxial cable; and a conductive interconnector connecting the first shield to the second shield. The secondary coil includes: a first core of the first coaxial cable; a second core of the second coaxial cable; and a pair of conductive lines connecting the first core to the second core.

In other features, the first coaxial cable extends parallel to the second coaxial cable. In other features, a sum of lengths of the first core, the second core and the pair of conductive lines is at least one of based or equal to a multiple of a length of each of the first coaxial cable and the second coaxial cable. In other features, a length of each of the first coaxial cable and the second coaxial cable is at least one of based on or equal to a fraction multiple of a wavelength of a radio frequency signal transmitted by the transformer.

In other features, a radio frequency distribution circuit is provided and includes a radio frequency generator and the transformer. The radio frequency generator is to generate a first radio frequency signal including a frequency component at a radio frequency. The transformer is to convert the first radio frequency signal to a second radio frequency signal, the second radio frequency signal includes a frequency component at the first radio frequency.

In other features, a substrate processing system is provided and includes the radio frequency distribution circuit, a process chamber, a showerhead, and a substrate support. The showerhead includes an electrode and implemented in the process chamber. The substrate support is implemented in the process chamber adjacent the showerhead. The transformer is to supply the second radio frequency signal to the electrode.

In other features, a radio frequency distribution circuit is provided and includes a first filter, a second filter, a first match network, a second match network, and a transformer coupled combiner. The first filter is to receive a first radio frequency signal and a second radio frequency signal from at least one radio frequency generator and filter out the first radio frequency signal, the first radio frequency signal is at a first frequency and the second radio frequency signal is at a second frequency, and the second frequency is less than the first frequency. The second filter is to receive the first radio frequency signal and the second radio frequency signal from the at least one radio frequency generator and filter out the first radio frequency signal. The first match network is to match an output of the at least one radio frequency generator to an input of the first filter. The second match network is to match an output of the at least one radio frequency generator to an input of the second filter. The transformer coupled combiner is to: convert the first radio frequency signal to a third radio frequency signal; convert the second radio frequency signal to a fourth radio frequency signal; and combine either the first radio frequency signal with the second radio frequency signal or the third radio frequency signal with the fourth radio frequency signal. The third radio frequency signal includes a frequency component at the first radio frequency. The fourth radio frequency signal includes a frequency component at the second radio frequency.

In other features, the transformer coupled combiner includes: a first transformer to receive an output of the first filter; and a second transformer to receive an output of the second filter.

In other features, the first transformer includes a primary coil and a secondary coil. The primary coil is connected to the first filter. The second transformer includes a primary coil and a secondary coil. The primary coil is connected to the second filter and the primary coil of the first transformer. The secondary coil is connected to the secondary coil of the first transformer.

In other features, the primary coil and the secondary coil of the first transformer are connected to a ground reference. The primary coil and the secondary coil of the second transformer are connected to the ground reference.

In other features, the first transformer includes a primary coil and a secondary coil. The primary coil includes: a first shield of a first coaxial cable; a second shield of a second coaxial cable; and a conductive interconnector connecting the first shield to the second shield. The secondary coil includes: a first core of the first coaxial cable; a second core of the second coaxial cable; and a pair of conductive lines connecting the first core to the second core.

In other features, the first coaxial cable extends parallel to the second coaxial cable. In other features, a sum of lengths of the first core, the second core and the pair of conductive lines is at least one of based on or equal to a multiple of a length of each of the first coaxial cable and the second coaxial cable. In other features, a length of each of the first coaxial cable and the second coaxial cable is at least one of based on or equal to a fraction multiple of a wavelength of the first radio frequency signal.

In other features, the transformer coupled combiner includes a first transformer. The first transformer includes: a first primary coil connected to the first filter; a second primary coil connected to the second filter; a first secondary coil connected to receive the third radio frequency signal; and a second secondary coil connected to receive the fourth radio frequency signal.

In other features, the first transformer includes a third secondary coil. The third secondary coil is to receive a fifth radio frequency signal. The fifth radio frequency signal includes a frequency component at the first frequency and a frequency component at the second frequency.

In other features, the transformer coupled combiner includes a first primary coil, a second primary coil, first secondary coil and a second secondary coil. The first primary coil is connected to the first filter. The second primary coil is connected to the second filter. The first secondary coil outputs the third radio frequency signal. The third radio frequency signal includes frequency components respectively at the first radio frequency and the second radio frequency. The second secondary coil outputs the fourth radio frequency signal. The fourth radio frequency signal includes frequency components respectively at the first radio frequency and the second radio frequency.

In other features, the transformer coupled combiner includes a third secondary coil and a fourth secondary coil. The third secondary coil outputs a fifth radio frequency signal. The fifth radio frequency signal includes frequency components respectively at the first radio frequency and the second radio frequency. The fourth secondary coil outputs a sixth radio frequency signal. The sixth radio frequency signal includes frequency components respectively at the first radio frequency and the second radio frequency.

In other features, a substrate processing system is provided and includes the radio frequency distribution circuit, a process chamber, a showerhead and a substrate support. The showerhead includes the electrode and implemented in the process chamber. The substrate support is implemented in the process chamber adjacent the showerhead.

A RF distribution circuit to supply RF power to an electrode in a substrate processing system is also provided and includes a first RF generator, a first filter, a first match network, and a first transformer. The first RF generator generates a first RF signal including a frequency component at a first RF. The first filter filters out one or more RF signals generated in the substrate processing system other than the first RF signal. The first match network matches an output of the first RF generator to an input of the first filter. The first transformer: converts the first RF signal to a second RF signal, where the second RF signal includes a frequency component at the first RF; and supplies the second RF signal to the electrode to adjust plasma ionization density and ionization energy within a process chamber of the substrate processing system.

In other features, a substrate processing system is provided and includes the RF distribution circuit, the process chamber, a showerhead and a substrate support. The showerhead includes the electrode and is implemented in the process chamber. The substrate support is implemented in the process chamber adjacent the showerhead.

In other features, the transformer includes a primary coil and a secondary coil. The primary coil includes a first shield of a first coaxial cable, a second shield of a second coaxial cable, and a conductive interconnector connecting the first shield to the second shield. The secondary coil includes a first core of the first coaxial cable, a second core of the second coaxial cable, and a pair of conductive lines connecting the first core to the second core. In other features, the first coaxial cable extends parallel to the second coaxial cable.

In other features, a sum of lengths of the first core, the second core and the pair of conductive lines is equal to four times a length of each of the first coaxial cable and the second coaxial cable. In other features, a length of each of the first coaxial cable and the second coaxial cable is equal to a quarter of a wavelength of the first RF signal.

In other features, the RF distribution circuit further includes: a second RF generator to generate a third RF signal including a frequency component at a second RF, where the second RF is less than the first RF; a second filter to filter out the first RF signal, where the first filter filters out the third RF signal; and a second match network to match an output of the second RF generator to an input of the second filter.

In other features, the RF distribution circuit further includes a second transformer to: receive an output of the second filter; convert the third RF signal to a fourth RF signal; and supply the fourth RF signal to the electrode.

In other features, a substrate processing system is provided and includes; the RF distribution circuit; the process chamber; a showerhead including the electrode and implemented in the process chamber; and a substrate support implemented in the process chamber adjacent the showerhead.

In other features, the first transformer includes a primary coil connected to the first filter and a secondary coil connected to the electrode. The second transformer includes: a primary coil connected to the second filter and the primary coil of the first transformer; and a secondary coil connected to the secondary coil of the first transformer and the electrode.

In other features, the primary coil and the secondary coil of the first transformer are connected to a ground reference. The primary coil and the secondary coil of the second transformer are connected to the ground reference.

In other features, the first transformer includes a primary coil and a secondary coil. The primary coil includes a first shield of a first coaxial cable, a second shield of a second coaxial cable, and a conductive interconnector connecting the first shield to the second shield. The secondary coil includes a first core of the first coaxial cable, a second core of the second coaxial cable, and a pair of conductive lines connecting the first core to the second core. In other features, the first coaxial cable extends parallel to the second coaxial cable. In other features, a sum of lengths of the first core, the second core and the pair of conductive lines is equal to four times a length of each of the first coaxial cable and the second coaxial cable. In other features, a length of each of the first coaxial cable and the second coaxial cable is equal to a quarter of a wavelength of the first RF signal.

In other features, the first transformer includes: a first primary coil connected to the first filter; a second primary coil connected to the second filter; and a first secondary coil connected to the electrode and to receive the first RF signal and the third RF signal. In other features, the electrode is a first electrode. The first transformer includes a second secondary coil connected to a second electrode and to receive the second RF signal and the fourth RF signal.

In other features, a substrate processing system is provided and includes the RF distribution circuit, the process chamber, a showerhead and a substrate support. The showerhead includes the electrode and implemented in the process chamber. The substrate support is implemented in the process chamber adjacent the showerhead.

In other features, the first transformer includes a third secondary coil connected to a third showerhead and to receive the second RF signal and the fourth RF signal. In other features, the first transformer includes: a first primary coil connected to the first filter; a second primary coil connected to the second filter; a first secondary coil connected to the electrode and outputting the second RF signal, where the second RF signal includes a frequency component at the second RF, and where the electrode is a first electrode; and a second secondary coil connected to a second electrode and outputting a fourth RF signal. The fourth RF signal includes frequency components respectively at the first RF and the second RF.

In other features, the first transformer includes: a third secondary coil outputting a fifth RF signal to a third electrode; the fifth RF signal includes frequency components respectively at the first RF and the second RF; a fourth secondary coil outputting a sixth RF signal to a fourth electrode; and the sixth RF signal includes frequency components respectively at the first RF and the second RF.

In other features, a RF distribution circuit to supply RF power to an electrode in a substrate processing system is provided and includes a RF generator, a transformer and a match network. The RF generator is to generate a first RF signal. The transformer is to convert the first RF signal to a second RF signal and to supply the second RF signal to the electrode to adjust plasma ionization density and ionization energy within a process chamber of the substrate processing system. The match network is to match an output of the RF generator to an input of the transformer. In other features, a substrate processing system is provided and includes the RF distribution circuit, the process chamber, a showerhead and a substrate support. The showerhead includes the electrode and implemented in the process chamber. The substrate support is implemented in the process chamber adjacent the showerhead.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1A is a Smith chart illustrating an example input impedance of a non-transformer based RF distribution circuit for a first load impedance;

FIG. 1B is a Smith chart illustrating another example input impedance of the RF distribution circuit for a second load impedance;

FIG. 1C is a Smith chart illustrating another example input impedance of the RF distribution circuit for a third load impedance;

FIG. 2 is a functional block diagram of an example of a substrate processing system incorporating a RF distribution circuit including a transformer in accordance with an embodiment of the present disclosure;

FIG. 3 is a functional block diagram of an example of a RF distribution circuit including a transformer in accordance with an embodiment of the present disclosure;

FIG. 4A is a Smith chart illustrating an example input impedance of the RF distribution circuit of FIG. 3 for a first load impedance;

FIG. 4B is a Smith chart illustrating another example input impedance of the RF distribution circuit of FIG. 3 for a second load impedance;

FIG. 5 is a functional block diagram of an example of a dual RF distribution circuit including a transformer coupled combiner in accordance with an embodiment of the present disclosure;

FIG. 6 is a Smith chart illustrating input impedances for short circuits, open circuits, and 50Ω providing load impedances for low-frequency (LF) and high-frequency (HF) paths of the dual RF distribution circuit of FIG. 5;

FIG. 7 is a functional block diagram of an example of a quad RF distribution circuit including a transformer coupled combiner in accordance with an embodiment of the present disclosure; and

FIG. 8 is a side view of an example transformer for a high-frequency RF signal in a RF distribution circuit in accordance with an embodiment of the present disclosure.

In the drawings, reference numbers may be reused to identify similar and/or identical elements.

### DETAILED DESCRIPTION

In semiconductor processing systems, it is common for two different RF frequencies to be supplied to provide independent control of plasma ionization density and ionization energy. A substrate processing system may include a processing chamber having a particular number of stations (e.g., 4 stations). Each of the stations may include a respective substrate support and a showerhead. The showerheads receive RF power from respective RF combiner and distribution circuits. Each of the RF combiner and distribution circuits may include LF and HF paths. The LF path generates a RF signal having a lower frequency than the RF signal generated by the HF path. As an example, the LF path may generate a 400 kilo-Hertz (kHz) RF signal and the HF path may generate a 13.56 mega-Hertz (MHz) RF signal. A LF generator generates a LF signal, which is provided to a first match network that feeds each of the LF paths of the RF combiner and distribution circuits. The first match network matches an impedance of an output of the LF generator with an input impedance collectively of the LF paths. A HF generator generates a HF signal, which is provided to a second match network that feeds each of the HF paths of the RF combiner and distribution circuits. The second match network matches an impedance of an output of the HF generator with an input impedance collectively of the HF paths.

The LF paths include respective LF ballast devices and LF filters to filter out the HF signal, such that the HF signal is not received at the LF generator. The HF paths include respective HF ballast devices and HF filters to filter out the LF signal, such that the LF signal is not received at the HF generator. The LF and HF ballast devices may include inductors and/or capacitors, which (i) isolate each of the stations from the other stations, and (ii) isolate inputs of the combiner and RF distribution circuits from load variation.

Each of the RF combiner and distribution circuits includes a switch for switching between a dummy load and the LF and HF paths. The dummy loads are used when the corresponding stations are not in use. This maintains approximately equal load across the stations. For example, when one or more of the stations are not in use, the switches of the stations that are in use are switched to permit LF and HF signals to pass from the RF generators to coaxial cables feeding corresponding ones of the electrodes of the stations. The switches of the one or more stations that are not in use are switched to the dummy loads and do not permit the LF and HF signals to pass via coaxial cables to corresponding electrodes of the one or more stations.

The RF combiner and distribution circuits are designed to resonate at high-frequency. This helps in developing high-voltages across electrodes which aids in providing fast and smooth ignition. The electrodes may refer to the showerheads and electrodes (or grounded conductive elements) in substrate supports of the stations.

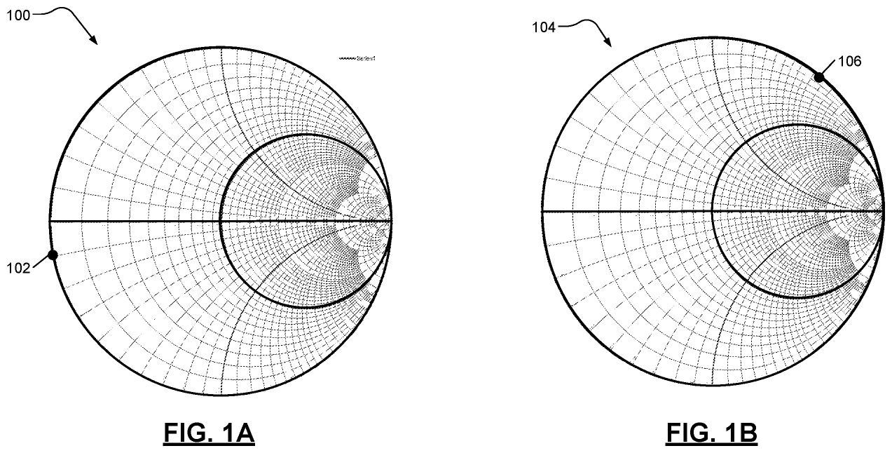

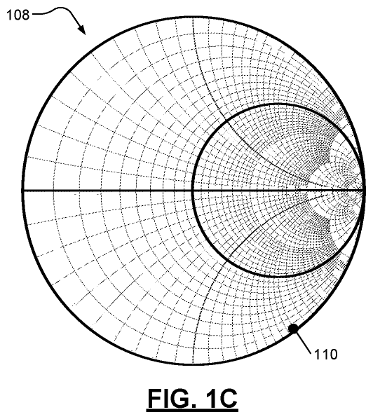

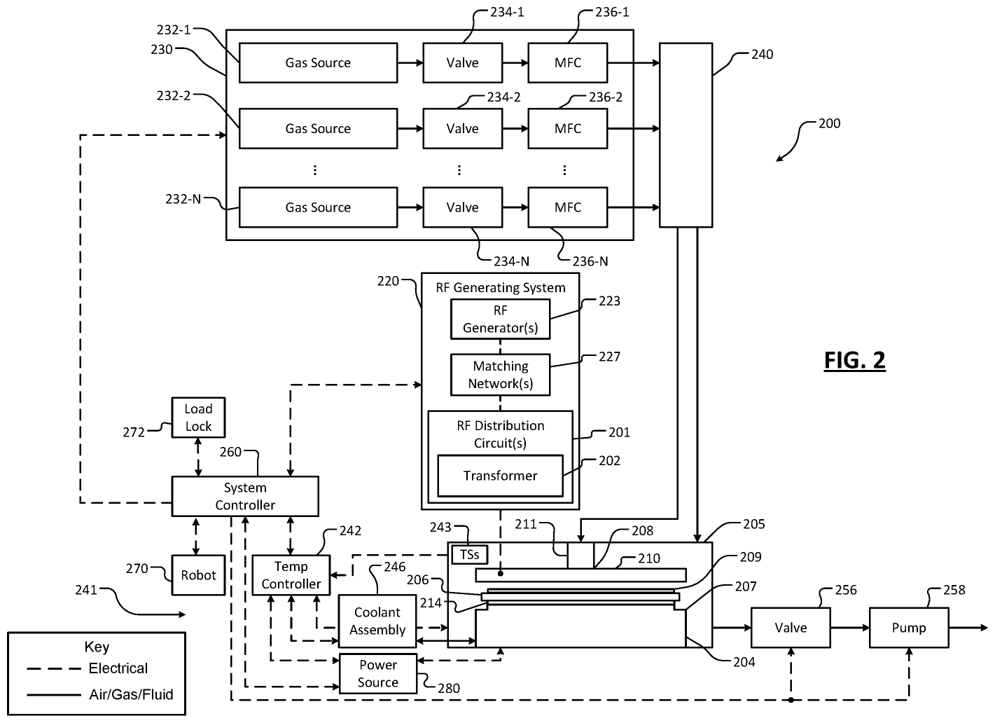

The RF combiner and distribution circuits experience large input impedance variations as a result of small changes in load impedance. As an example, FIGS. 1A-1C are provided to illustrate three different input impedances for three different load impedances. FIGS. 1A-1C include Smith charts 100, 104, 108, which are logarithmic representations of possible input impedance values. As an example, the load impedance (or impedance at a showerhead) may be 132 pico-Farad (pF), which results in an input impedance illustrated by dot 102 in FIG. 1A. The load impedance may change to 230 pF, which may result in a change in the input impedance as illustrated by dot 106 in FIG. 1B. The load impedance may again change to 240 pF, which may result in a change in the input impedance as illustrated by dot 110 in FIG. 1C. As shown by these plots, a small change in load impedance, results in a large location change in the Smith charts 100, 104, 108 of the dots 102, 106, 110, which corresponds to a large variation in input impedance. In a processing chamber that includes multiple stations, a change in a load impedance of one station can also negatively affect performance in the other stations.

Since the RF combiner and distribution circuits exhibit large changes in input impedances as a result of small changes in load impedances, auto-match circuits are used for tuning the match networks. Also, for different types of substrate processes to be run using the same substrate processing tool, auto-match circuits with a large tuning range are used. In addition, the RF combiner and distribution circuits require high-impedance ballast devices for isolation. The high-impedance ballast devices reduce current flow to the corresponding stations. Also, sizes of match network components, ballast devices, and filter components increases with increase in power. The topology of the RF combiner and distribution circuits is inherently unbalanced.

If processes are to be performed that do not utilize all stations of a process chamber, then the required tuning range of the auto-match circuits substantially increases. A multi-station tool, unlike a single station tool, includes multiple showerheads that each receive generated RF signals. If one or more of the stations are not utilized, then the load impedance for that station is substantially different than for the other stations. This requires the auto-match circuits for the stations to have larger tuning ranges to compensate for this loading imbalance of the stations.

The examples set forth herein overcome the disadvantages described above and provide substrate processing systems including RF distribution circuits including one or more transformers and/or transformer coupled combiners. The transformers and/or transformer coupled combiners minimize input impedance variation as a result of changes in load impedances. Some of the disclosed RF distribution circuits include efficient combiner circuits. As used herein a “combiner circuit” combines two or more RF signals into a single RF signal.

The RF distribution circuits provide station-to-load, station-to-station and input-to-output isolation to minimize effects on certain stations due to a variation in load impedance at another station. The RF distribution circuits provide self-sustaining systems that: exhibit decreased sensitivity to load impedance variation; allow for a broad range of recipes for substrate processing with a large range of corresponding load impedances; experience minimal input impedance variation due to loading and unloading of substrates in and out of a processing chamber; and allow for each leg (or RF signal path to each station) to be at or near resonance for fast and smooth ignition associated with plasma generation. In certain embodiments, the RF combiner and distribution circuits combine two or more RF frequency signals and supply signals having two or more frequencies to one or more stations. The RF distribution circuits allow for impedance matching for both LF and HF signals. Other advantages and aspects of the RF distribution circuits set forth herein are further described below.

FIG. 2 is a functional block diagram of an example of a substrate processing system 200 incorporating a RF distribution circuit 201 including a transformer 202. The RF distribution circuit 201 may be configured the same or similarly as any of the RF distribution circuits disclosed herein. The transformer 202 may be configured as any transformer and/or transformer coupled combiner disclosed herein. Although FIG. 1 shows a capacitive coupled plasma (CCP) system, the embodiments disclosed herein are applicable to other plasma processing systems. The embodiments are applicable to deposition, etch, and other substrate treatment processes including plasma enhanced atomic layer deposition (PEALD) and plasma enhanced chemical vapor deposition (PECVD) processes.

The substrate processing system 200 includes one or more stations, each of which having a respective substrate support, such as an electrostatic chuck (ESC) 204. The one or more stations are disposed in a processing chamber 205. The ESC 204 may include a top plate 206 and a baseplate 207. Other components, such as an upper electrode 208, may be disposed in the processing chamber 205. During operation, a substrate 209 is arranged on and electrostatically clamped to the top plate 206 of the ESC 204 and RF plasma is generated within the processing chamber 205.

For example only, the upper electrode 208 may include a showerhead 210 that introduces and distributes gases. The showerhead 210 may include a stem portion 211 including one end connected to a top surface of the processing chamber 205. The showerhead 210 is generally cylindrical and extends radially outward from an opposite end of the stem portion 211 at a location that is spaced from the top surface of the processing chamber 205. A substrate-facing surface of the showerhead 210 includes holes through which process or purge gas flows. Alternately, the upper electrode 208 may include a conducting plate and the gases may be introduced in another manner. One or both of the plates 206, 207 may perform as a lower electrode.

One or both of the plates 206, 207 may include temperature control elements (TCEs). An intermediate layer 214 is arranged between the plates 206, 207. The intermediate layer 214 may bond the top plate 206 to the baseplate 207. The baseplate 207 may include one or more gas channels and/or one or more coolant channels for flowing backside gas to a backside of the substrate 209 and coolant through the baseplate 207.

An RF generating system 220 generates and outputs RF voltages to the upper electrode 208. The RF generating system 220, may generate and output RF voltages to the ESC 204. One of the upper electrode 208 and the ESC 204 may be DC grounded, AC grounded or at a floating potential. For example only, the RF generating system 220 may include one or more RF generators 223 (e.g., a capacitive coupled plasma RF power generator and/or other RF power generator) that generate RF voltages, which are fed by one or more match networks 227 and RF distribution circuits 201 to the upper electrode 208. The RF generators 223 may be high-power RF generators producing, for example, 6-10 kilo-watts (kW) of power or more. The RF generators 223 may generate respective RF signals having frequency components at respective RF frequencies.

A gas delivery system 230 includes one or more gas sources 232-1, 232-2, . . . , and 232-N (collectively gas sources 232), where N is an integer greater than zero. The gas sources 232 supply one or more precursors and gas mixtures thereof. The gas sources 232 may also supply etch gas, carrier gas and/or purge gas. Vaporized precursor may also be used. The gas sources 232 are connected by valves 234-1, 234-2, . . . , and 234-N (collectively valves 234) and mass flow controllers 236-1, 236-2, . . . , and 236-N (collectively mass flow controllers 236) to a manifold 240. An output of the manifold 240 is fed to the processing chamber 204. For example only, the output of the manifold 140 is fed to the showerhead 210.

The substrate processing system 200 further includes a cooling system 241 that includes a temperature controller 242, which may be connected to the TCEs. Although shown separately from a system controller 260, the temperature controller 242 may be implemented as part of the system controller 260. One or more of the plates 206, 207 may include multiple temperature controlled zones (e.g., 4 zones, where each of the zones includes 4 temperature sensors).

The temperature controller 242 may control operation and thus temperatures of the TCEs to control temperatures of the plates 206, 207 and a substrate (e.g., the substrate 209). The temperature controller 242 and/or the system controller 260 may control flow rate of backside gas (e.g., helium) to the gas channels ESC 204 for cooling the substrate by controlling flow from one or more of the gas sources 232 to the gas channels. The temperature controller 242 may also communicate with a coolant assembly 246 to control flow of a first coolant (pressures and flow rates of a cooling fluid) through channels in the ESC 204. The first coolant assembly 246 may receive a cooling fluid from a reservoir (not shown). For example, the coolant assembly 246 may include a coolant pump and reservoir. The temperature controller 242 operates the coolant assembly 246 to flow the coolant through the channels 216 to cool the baseplate 207. The temperature controller 242 may control the rate at which the coolant flows and a temperature of the coolant. The temperature controller 242 controls current supplied to the TCEs and pressure and flow rates of gas and/or coolant supplied to channels based on detected parameters from sensors 243 within the processing chamber 205. The temperature sensors 243 may include resistive temperature devices, thermocouples, digital temperature sensors, and/or other suitable temperature sensors. During an etch process, the substrate 209 may be heated up by a predetermined temperature (e.g., 120 degrees Celsius (° C.)) in presence of high-power plasma. Flow of gas and/or coolant through the channels reduces temperatures of the baseplate 207, which reduces temperatures of the substrate 209 (e.g., cooling from 120° C. to 80° C.).

A valve 256 and pump 258 may be used to evacuate reactants from the processing chamber 205. The system controller 260 may control components of the substrate processing system 200 including controlling supplied RF power levels, pressures and flow rates of supplied gases, RF matching, etc. The system controller 260 controls states of the valve 256 and the pump 258. A robot 270 may be used to deliver substrates onto, and remove substrates from, the ESC 204. For example, the robot 270 may transfer substrates between the ESC 204 and a load lock 272. The robot 270 may be controlled by the system controller 260. The system controller 260 may control operation of the load lock 272.

A power source 280 may provide power, including a high voltage to electrodes in the ESC 204 to electrostatically clamp the substrate 209 to the top plate 206. The power source 280 may be controlled by the system controller 260.

The valves, gas and/or coolant pumps, power sources, RF generators, etc. may be referred to as actuators. The TCEs, gas channels, coolant channels, etc. may be referred to as temperature adjusting elements.

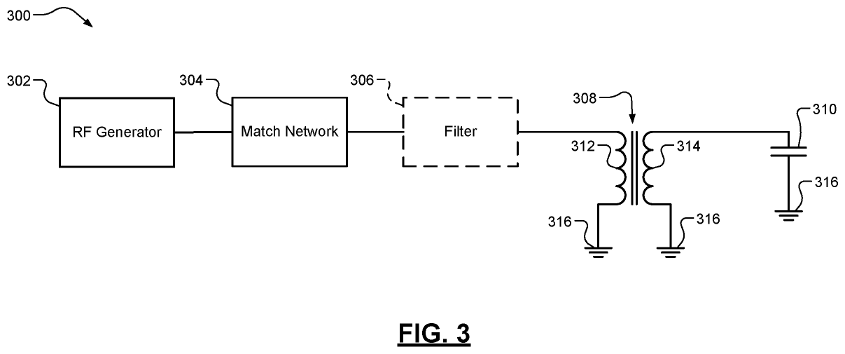

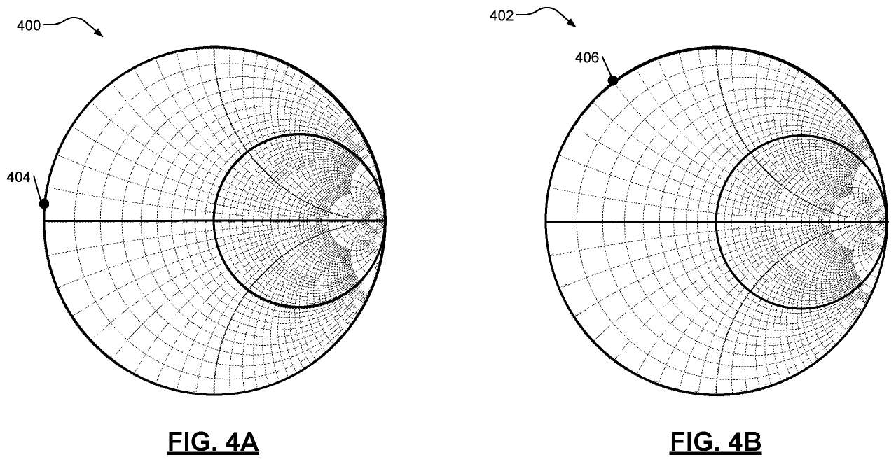

Referring now to FIG. 2 and FIG. 3, which shows a RF distribution circuit 300 that may include a RF generator 302, a match network 304, a filter 306, a transformer 308, and a load 310. In an embodiment, the filter 306 is not included. The load 310 is shown as a capacitor and may represent an impedance between, for example, the showerhead 210 and a ground reference 316. The RF generator 302 may be one of the RF generators 223 and generates an RF signal. The match network 304 may be one of the match networks 227 and matches impedances of (i) the output of the RF generator 302, and (ii) the input of the filter 306 and/or transformer 308. The match network 304 may perform an auto-match operation including tuning one or more components to impedance match the output of the RF generator 302 and the input of the filter 306 and/or transformer 308. This may include tuning, for example, a capacitor of the match network 304.

The filter 306, if included, may filter out one or more RF signals generated by one or more other RF generators other than the RF generator 302. The filter 306 permits the RF signal generated by the RF generator to pass to the transformer 308.

The transformer 308 includes a primary coil 312 and a secondary coil 314, which have a corresponding winding and/or voltage conversion ratio. As a couple of examples, the ratio may be 3:4 or 1:2. The transformer 308 may convert a first radio frequency signal at a frequency received from the match network 304 or the filter 306 to a second radio frequency signal at the same frequency. The transformer 308 may then provide the second radio frequency signal to, for example, an electrode and/or showerhead to adjust plasma ionization density and ionization energy within a process chamber.

The transformer 308 serves multiple functions including providing ballasting and isolation between the primary and secondary sides of the transformer 308 and thus isolation between (i) the RF generator 302 and match network 304 and (ii) the load 310. In an embodiment, no ballast device is connected (i) between the RF generator 302 and the match network 304, (ii) between the match network 304 and the filter 306, (iii) between the filter 306 and the transformer 308, and/or (iv) between the match network 304 and the transformer 308. The described isolation reduces the effect of load impedance changes on corresponding input circuit (or RF generator 302 and match network 304). The impedance of the load 310 can vary during processing of a substrate. The amount of variation is based on the recipe and the process being performed. By selecting the appropriate transformer ratio, input impedance variation is also controlled. Input impedance refers to the impedance of the input of the filter 306 seen by the match network 304. The transformer 308 also allows for faster tuning of components of the match network 304 because the associated changes in input impedance are reduced relative to changes in load impedance. The transformer 308 also minimizes the amount of reflected power received at the RF generator 302 and allows for high power (e.g., 10 KW) to be supplied to the load 310.

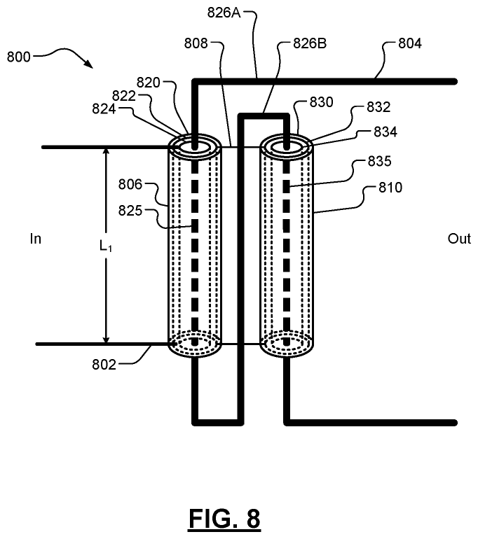

Although a single RF distribution circuit 300 is shown in FIG. 3, multiple RF distribution circuits of the type shown in FIG. 3 may be used to supply RF power to respective stations of a process chamber. The secondary windings of the transformers may supply power via respective coaxial cables to the stations as similarly shown in FIG. 7. Also, switches and corresponding dummy loads may be included for each of the stations as shown in FIG. 7. The switches may be controlled by one of the controllers 242, 260 of FIG. 2.

FIGS. 4A and 4B show Smith charts 400, 402 illustrating example input impedances of the RF distribution circuit 300 of FIG. 3 for a first load impedance and a second load impedance. The input impedances are represented by dots 404, 406. In the example shown, the first load impedance is 130 pico-farad (pF) and the second load impedance is 3,000,000 pF. As can be seen from the Smith charts 400, 402, the distance between the dots 404, 406 and thus the difference in the input impedances as compared to the difference in the load impedances is minimal.

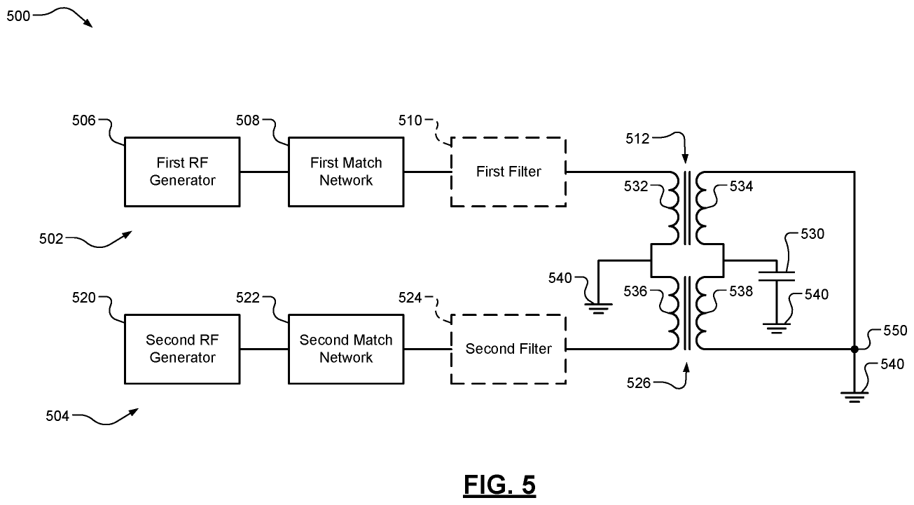

FIG. 5 shows a dual RF distribution circuit 500 that includes a first (or high) RF path 502 and a second (or low) RF path 504. The first RF path 502 includes a first RF generator 506, a first match network 508, a first filter 510 and a first transformer 512 having a first transformer ratio. The second RF path 504 includes a second RF generator 520, a second match network 522, a second filter 524 and a second transformer 526 having a second transformer ratio. The first transformer 512 is connected to the second transformer 526. The transformers 512, 526 provide a transformer coupled combiner, which combines two RF signals generated by the RF paths 502, 504 to provide a single RF signal to a load 530. The single RF signal has the frequency components of the two RF signals. The transformers 512, 526 convert the two RF signals to the single RF signal. This may include changing, for example, the amplitude of the two RF signals to provide a single RF signal with a different amplitude than the two RF signals. The load 530 is shown as a capacitor, which represents a load impedance between, for example, the showerhead 210 of FIG. 2 and a ground reference 540. The load 530 may be one or more electrodes of one or more processing stations in one or more processing chambers, where each station may include one or more electrodes and each processing chamber may include one or more stations.

The RF generators 506, 520 generate respective RF signals. As an example, the first RF generator 506 may generate a 13.56 MHz RF signal and the second RF generator 520 may generate a 400 kHz signal. The first match network 508 may match an output impedance of the first RF generator 506 to an input impedance of the first filter 510. The second match network 522 may match an output impedance of the second RF generator 520 to an input impedance of the second filter 524.

The first filter 510 performs as a high pass filter and (i) permits passage of the first RF signal generated by the first RF generator 506 to pass to the first transformer 512, and (ii) prevents a RF signal generated by the second RF generator 520 from being received at the first RF generator 506. The second filter 524 performs as a low pass filter and (i) permits passage of the second RF signal generated by the second RF generator 520 to pass to the second transformer 526, and (ii) prevents the RF signal generated by the first RF generator 506 from being received at the second RF generator 520. Both of the RF generators 506, 520 may be matched properly by including separate primary coils for the RF paths 502, 504, as shown, and choosing an appropriate number of primary windings of each of the primary coils and including the appropriate matching circuitry in the match networks 508, 522.

The first transformer 512 includes a primary coil 532 and a secondary coil 534. The second transformer 526 includes a primary coil 536 and a secondary coil 538. First ends of the primary coils 532, 536 are connected to the filters 510, 524. In one embodiment, the filters 510, 524 are not included and the primary coils 532, 536 are connected to the match networks 508, 522. Second ends of the primary coils 532, 536 are connected to the ground reference 540. First ends of the secondary coils 534, 538 are connected to the ground reference 540. Second ends of the secondary coils 534, 538 are connected to the load 530. The first transformer 512 may convert a first radio frequency signal at a first frequency received from the first filter 510 to a second radio frequency signal at the first frequency. The second transformer 526 may convert a third radio frequency signal at a second frequency received from the second filter 524 to a fourth radio frequency signal at the second frequency. The transformers 512, 526 may then provide the second radio frequency signal and the fourth radio frequency signal to, for example, an electrode and/or showerhead to adjust plasma ionization density and ionization energy within a process chamber.

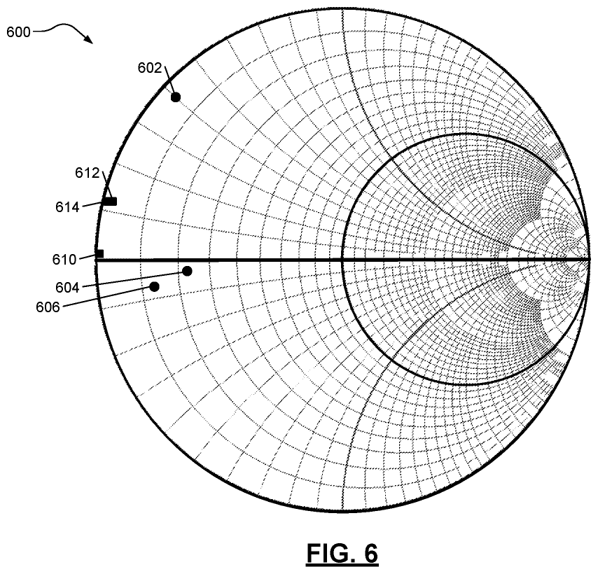

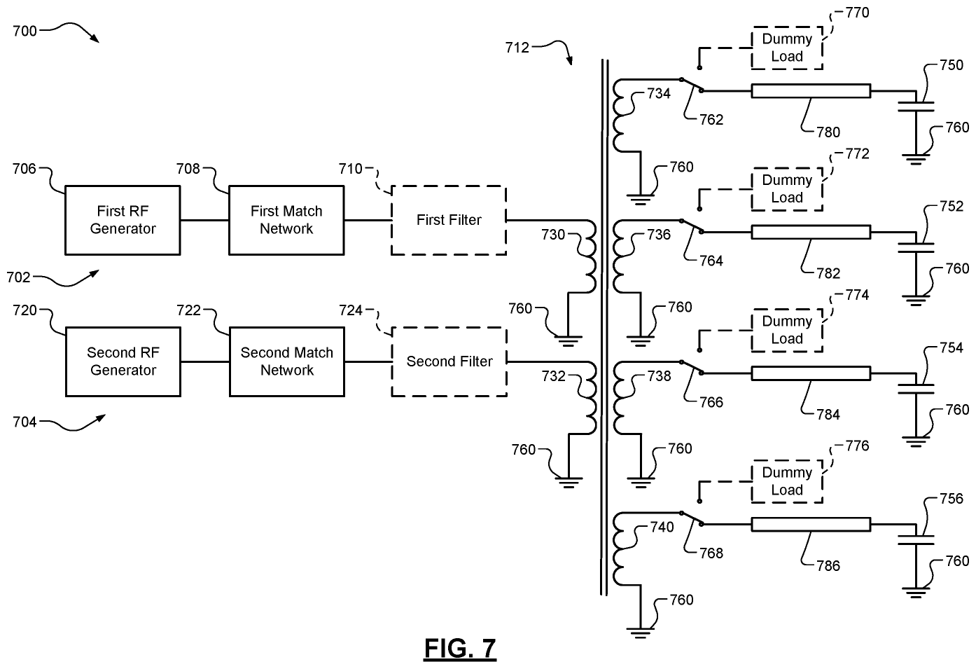

Examples of the changes in input impedance variations for the LF and HF paths are illustrated by the Smith chart 600 of FIG. 6. The Smith chart 600 illustrates input impedances for short circuits, open circuits, and 50Ω providing load impedances for LF and HF paths 502, 504 of FIG. 5. In FIG. 6, circular dots are shown and correspond to the HF paths and square dots are shown and correspond to the LF paths. The Smith chart 600 is a logarithmic representation of possible input impedance values. When the input impedance changes, the corresponding dot moves to a different location on the Smith chart.

Dots 602, 604, 606 represent respectively input impedances for a short circuit, an open circuit, and a 50Ω providing load impedance for the HF path 502. The 50Ω providing load impedance refers to a load impedance that provides a 50Ω input impedance. Dots 610, 612, 614 represent respectively input impedances for a short circuit, an open circuit, and a 50Ω providing load impedance for the LF path 504. A short circuit refers to a direct or indirect conductive connection (or path) between the showerhead 210 and the ground reference 540. The short circuit refers to when the load impedance is 0Ω. An open circuit refers to there being no conductive path between the showerhead 210 and the ground reference 540. The open circuit refers to when the load impedance is approaching infinity. As can be seen from the Smith Chart the distances between the dots (or points) 602, 604, 606 and the distances between the dots (or points) 610, 612, 614 are minimal and are not disposed across the whole Smith chart, but rather are located in a small portion of the Smith chart. Thus, the differences in corresponding input impedances are also minimal.

The transformers 512, 526 serve multiple functions including providing ballasting and isolation between the primary and secondary sides of the transformers 512, 526, similar to the transformer 308 of FIG. 3. In an embodiment, no ballast device is connected (i) between the RF generators 506, 520 and the match networks 508, 522, (ii) between the match networks 508, 522 and the filters 510, 524, (iii) between the filters 510, 524 and the transformers 512, 526, and/or (iv) between the match networks 508, 522 and the transformers 512, 526.

Although a single RF distribution circuit 500 is shown in FIG. 5, multiple RF distribution circuits of the type shown in FIG. 5 may be used to supply RF power to respective stations of a process chamber. The secondary windings of the transformers may supply power via corresponding coaxial cables to the stations as similarly shown in FIG. 7. Also, switches and corresponding dummy loads may be included for each of the stations as shown in FIG. 7. As an example a switch may be connected downstream from terminal 550 and switch between (i) a respective coaxial cable connected to an electrode and/or showerhead, and (ii) a dummy load. The switches may be controlled by one of the controllers 242, 260 of FIG. 2.

FIG. 7 shows a quad RF distribution circuit 700 includes a first (or high) RF path 702 and a second (or low) RF path 704. The first RF path 702 includes a first RF generator 706, a first match network 708, and a first filter 710. The second RF path 704 includes a second RF generator 720, a second match network 722, and a second filter 724. The quad RF distribution circuit 700 includes a transformer 712 having two inputs, 4 outputs and a transformer ratio that is shared by the 4 outputs. The 4 outputs feed 4 channels, which are connected to 4 loads (or showerheads) 750, 752, 754, 756 of 4 stations of a processing chamber.

The RF generators 706, 720 generate respective RF signals. As an example, the first RF generator 706 may generate a 13.56 MHz RF signal and the second RF generator 720 may generate a 400 KHz signal. The first match network 708 may match an output impedance of the first RF generator 706 to an input impedance of the first filter 710. The second match network 722 may match an output impedance of the second RF generator 720 to an input impedance of the second filter 724. The first filter 710 performs as a high pass filter and (i) permits passage of the first RF signal generated by the first RF generator 706 to pass to the first transformer 712, and (ii) prevents a RF signal generated by the second RF generator 720 from being received at the first RF generator 706. The second filter 724 performs as a low pass filter and (i) permits passage of the second RF signal generated by the second RF generator 720 to pass to the transformer 712, and (ii) prevents the RF signal generated by the first RF generator 706 from being received at the second RF generator 720. Both of the RF generators 706, 720 may be matched properly by including separate primary coils (or primary windings) for the RF paths 702, 704, as shown, and choosing an appropriate number of primary turns of each of the primary coils and including the appropriate matching circuitry in the match networks 708, 722.

The transformer 712 is a transformer coupled combiner, which combines two RF signals generated by the RF paths 702, 704 to provide 4 RF signals, which are provided to the loads 750, 752, 754, 756. The loads 750, 752, 754, 756 are shown as capacitors, which represent a load impedances between, for example, the showerheads and the ground reference 760. Although the transformer 712 is shown as having two inputs and four outputs, the transformer 712 may have two or more inputs and one or more outputs.

The transformer 712 includes a first primary coil 730, a second primary coil 732, a first secondary coil 734, a second secondary coil 736, a third secondary coil 738 and a fourth secondary coil 740. In an embodiment, the primary coils 730, 732 have a same number of windings and the secondary coils 734, 736, 738, 740 have a same number of windings. First ends of the primary coils 730, 732 are connected to the filters 710, 724. In one embodiment, the filters 710, 724 are not included and the first ends of the primary coils 730, 732 are connected to the match networks 708, 722. Second ends of the primary coils 730, 732 are connected to the ground reference 760. First ends of the secondary coils 734, 736, 738, 740 are connected respectively to the loads 750, 752, 754, 756. Second ends of the secondary coils 734, 736, 738, 740 are connected to the ground reference 760. The transformer receives the RF signals from the paths 702, 704, combines the signals and provides a combined RF signal to each of the loads 750, 752, 754, 756 via the secondary coils 734, 736, 738, 740.

The transformer 712 may convert and combine a first radio frequency signal at a first frequency received from the first filter 710 and a second radio frequency signal at a second frequency received from the second filter 724 to a third radio frequency signal. The third radio frequency signal includes both the first radio frequency and the second radio frequency. The transformer 712 may then provide the third radio frequency signal to, for example, an electrode and/or showerhead to adjust plasma ionization density and ionization energy within a process chamber.

The transformer 712 serves multiple functions including providing ballasting and isolation between the primary and secondary sides of the transformer 712, similar to the transformer 308 of FIG. 3. In an embodiment, no ballast device is connected (i) between the RF generator 506, 520 and the match networks 508, 522, (ii) between the match networks 508, 522 and the filters 510, 524, (iii) between the filters 510, 524 and the transformers 512, 526, and/or (iv) between the match networks 508, 522 and the transformers 512, 526.

In an embodiment, the secondary coils 734, 736, 738, 740 may be connected to switches 762, 764, 766, 768, which may switch between the loads 750, 752, 754, 756 and dummy loads 770, 772, 774, 776. In another embodiment, the switches 762, 764, 766, 768 and the dummy loads 770, 772, 774, 776 are not included. The secondary coils 734, 736, 738, 740 or the switches 762, 764, 766, 768 may be connected to the loads 750, 752, 754, 756 via coaxial cables 780, 782, 784, 786. The switches 762, 764, 766, 768 may be controlled by one of the controllers 242, 260 of FIG. 2. One or more of the dummy loads 770, 772, 774, 776 may be connected when, for example, a substrate is not being processed in one or more of the corresponding stations as described above.

Some of the RF combiner circuits disclosed herein, such as that shown in FIG. 7, provide balanced distribution systems that split a combined RF signal into n equal channels, where n is an integer greater than or equal to two. The outputs of the n channels are isolated from each other, such that change in one of the channels does not affect or minimally affects change in the other channels. The inputs of the channels are isolated from the input of the transformer 712. The RF combiner circuits provide fast and smooth ignition for plasma generation.

The Examples of FIGS. 3, 5, and 7 are configured such that each of the RF distribution circuits 300, 500, 700 may be used for multiple different substrate processes. The processes may include etching, depositing and/or other substrate treatment processes.

FIG. 8 shows a side view of an example transformer 800 that may be used for a high-frequency RF signal in a RF distribution circuit. As an example, the transformers 308, 512 of FIGS. 3 and 5 may each be replaced with the transformer 800. The transformer 800 is a coaxial transformer and may include a primary coil 802 and a secondary coil 804. The primary coil 802 includes (i) conductive shields 822, 832 of two coaxial cables 806, 810, and (ii) a conductive interconnector 808. The conductive interconnector 808 extends through non-conductive sheaths 820, 830 of the coaxial cables 806, 810 and is connected to the conductive shields 822, 832. The conductive interconnector may be a conductive plate, or other suitable interconnector that maintains position of the second coaxial cable 810 relative to the first coaxial cable 806.

The coaxial cables 806, 810 extend parallel to each other and further include conductive cores 825, 835 that are isolated from the conductive sheaths 820, 830 by inner dielectric insulators 824, 834. The conductive cores 825, 835 are connected in a series loop by conductive lines 826A, 826B. The conductive line 826A connects a first end of the first coaxial cable 806 to a first end of the second coaxial cable 810. The first end of the second coaxial cable 810 is at an opposite end of the conductive interconnector 808 than the first end of the first coaxial cable 806. The conductive line 826B connects a second end of the first coaxial cable 806 to a second end of the second coaxial cable 810. The second end of the second coaxial cable 810 is at an opposite end of the conductive interconnector 808 than the second end of the first coaxial cable 806.

As an example, the conductive shields 822, 832, the conductive cores 825, 835, and the conductive lines 826A, 826B may be formed of copper and/or other suitable material that exhibits a minimal amount of heating during use. The non-conductive sheaths 820, 830 may be formed of plastic. The inner dielectric insulators 824, 834 are non-conductive and may be formed of various dielectric materials, such as polyethylene (PE) and polytetrafluoroethylene (PTFE). In an embodiment, no sheath, shield and/or inner dielectric insulator is on the conductive lines 826A, 826B, as shown.

It can be difficult to manufacture a low-frequency transformer that is capable of handling high-radio frequencies of, for example, greater than 1 mega-Hertz (MHz) without having the transformer overheat. The permeability (or distributed inductance) of the transformer may need to be reduced and the transformer may need to be formed of special materials. The transformer 800 may be used for high-radio frequencies, microwave frequencies, etc. A length L₁ of the coaxial cables 806, 810 may be based on and/or equal to a fraction multiple of a wavelength of the RF being transmitted. As an example, the fraction multiple may be, for example, less than one half (½) a wavelength of the RF being transmitted. In an embodiment, the length L₁ of the coaxial cables 806, 810 is equal to a quarter (¼) wavelength of the RF being transmitted. The quarter wavelength (or multiple of it) has an advantage in that it converts the corresponding impedance of the transformer from 0 Ohms (Ω) (or short circuit) to infinite Ω (or open circuit) or vice versa depending on the circuit. The overall length of the series loop provided by the conductive cores 825, 835 and the conductive lines 826A, 826B may be based on and/or equal to a multiple of the length L₁. In an embodiment, an overall length of the series loop provided by the conductive cores 825, 835 and the conductive lines 826A, 826B is equal to four times the length L₁ (or 4L₁). As an example, the transformer ratio of the transformer 800 may be 1:2 between the primary winding and the secondary winding, where: the primary winding is implemented as the primary coil 802 and includes an input of the transformer 800; and the second winding is implemented as the secondary coil 804 and provides an output of the transformer 800. Although the coaxial cables 806, 810 may be formed similar to RG58C coaxial cables, RG58C coaxial cables would not be suitable for high-power applications, such as that associated with substrate processing systems. The sizes and/or materials of the coaxial cables 806, 810 may be different than that of RG58C coaxial cables.

The above-disclosed RF distribution circuits exhibit: high input-to-output isolation, such that sensitivity of input impedance to change in load impedance is decreased; improved station-to-station isolation; and impedance matching for LF and HF paths. The above-disclosed RF distribution circuits are also robust and provide increased reliability over traditional RF combiner and distribution circuits. The disclosed RF distribution circuits: include balanced stations; exhibit fast tuning; allow for RF signals to be supplied to multiple stations; exhibit low reflected power on both LF and HF generators; and provide unconditionally stable systems. The RF distribution circuits are also capable of supplying high power (e.g., 10 kilo-watt (KW) HF and 8 KW LF) RF signals.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A transformer comprising:
a primary coil comprising
a first shield of a first coaxial cable,
a second shield of a second coaxial cable, and
a conductive interconnector connecting the first shield to the second shield; and
a secondary coil comprising
a first core of the first coaxial cable,
a second core of the second coaxial cable, and
a pair of conductive lines connecting the first core to the second core.

2. The transformer of claim 1, wherein the first coaxial cable extends parallel to the second coaxial cable.

3. The transformer of claim 1, wherein a sum of lengths of the first core, the second core and the pair of conductive lines is at least one of based or equal to a multiple of a length of each of the first coaxial cable and the second coaxial cable.

4. The transformer of claim 1, wherein a length of each of the first coaxial cable and the second coaxial cable is at least one of based on or equal to a fraction multiple of a wavelength of a radio frequency signal transmitted by the transformer.

5. A radio frequency distribution circuit comprising:
a radio frequency generator to generate a first radio frequency signal including a frequency component at a radio frequency; and
the transformer of claim 1, wherein the transformer is to convert the first radio frequency signal to a second radio frequency signal, the second radio frequency signal includes a frequency component at the first radio frequency.

6. A substrate processing system comprising:
the radio frequency distribution circuit of claim 5;
a process chamber;
a showerhead comprising an electrode and implemented in the process chamber; and
a substrate support implemented in the process chamber adjacent the showerhead,
wherein the transformer is to supply the second radio frequency signal to the electrode.

7. A radio frequency distribution circuit comprising:
a first filter to receive a first radio frequency signal and a second radio frequency signal from at least one radio frequency generator and filter out the first radio frequency signal, the first radio frequency signal is at a first frequency and the second radio frequency signal is at a second frequency, and the second frequency is less than the first frequency;
a second filter to receive the first radio frequency signal and the second radio frequency signal from the at least one radio frequency generator and filter out the first radio frequency signal;
a first match network to match an output of the at least one radio frequency generator to an input of the first filter;
a second match network to match an output of the at least one radio frequency generator to an input of the second filter; and
a transformer coupled combiner to convert the first radio frequency signal to a third radio frequency signal, convert the second radio frequency signal to a fourth radio frequency signal, and combine either the first radio frequency signal with the second radio frequency signal or the third radio frequency signal with the fourth radio frequency signal, the third radio frequency signal includes a frequency component at the first radio frequency, and the fourth radio frequency signal includes a frequency component at the second radio frequency.

8. The radio frequency distribution circuit of claim 7, wherein the transformer coupled combiner comprises:
a first transformer to receive an output of the first filter; and
a second transformer to receive an output of the second filter.

9. The radio frequency distribution circuit of claim 8, wherein:
the first transformer comprises
a primary coil connected to the first filter, and
a secondary coil; and
the second transformer comprises
a primary coil connected to the second filter and the primary coil of the first transformer, and
a secondary coil connected to the secondary coil of the first transformer.

10. The radio frequency distribution circuit of claim 9, wherein:
the primary coil and the secondary coil of the first transformer are connected to a ground reference, and
the primary coil and the secondary coil of the second transformer are connected to the ground reference.

11. The radio frequency distribution circuit of claim 9, wherein the first transformer comprises:
a primary coil comprising
a first shield of a first coaxial cable,
a second shield of a second coaxial cable, and
a conductive interconnector connecting the first shield to the second shield; and
a secondary coil comprising
a first core of the first coaxial cable,
a second core of the second coaxial cable, and
a pair of conductive lines connecting the first core to the second core.

12. The radio frequency distribution circuit of claim 11, wherein the first coaxial cable extends parallel to the second coaxial cable.

13. The radio frequency distribution circuit of claim 11, wherein a sum of lengths of the first core, the second core and the pair of conductive lines is at least one of based on or equal to a multiple of a length of each of the first coaxial cable and the second coaxial cable.

14. The radio frequency distribution circuit of claim 11, wherein a length of each of the first coaxial cable and the second coaxial cable is at least one of based on or equal to a fraction multiple of a wavelength of the first radio frequency signal.

15. The radio frequency distribution circuit of claim 7, wherein:
the transformer coupled combiner comprises a first transformer; and
the first transformer comprises
a first primary coil connected to the first filter,
a second primary coil connected to the second filter,
a first secondary coil connected to receive the third radio frequency signal, and
a second secondary coil connected to receive the fourth radio frequency signal.

16. The radio frequency distribution circuit of claim 15, wherein:
the first transformer comprises a third secondary coil;
the third secondary coil is to receive a fifth radio frequency signal; and
the fifth radio frequency signal includes a frequency component at the first frequency and a frequency component at the second frequency.

17. The radio frequency distribution circuit of claim 7, wherein the transformer coupled combiner comprises:
a first primary coil connected to the first filter;
a second primary coil connected to the second filter;
a first secondary coil outputting the third radio frequency signal, the third radio frequency signal includes frequency components respectively at the first radio frequency and the second radio frequency; and
a second secondary coil outputting the fourth radio frequency signal, the fourth radio frequency signal includes frequency components respectively at the first radio frequency and the second radio frequency.

18. The radio frequency distribution circuit of claim 17, wherein the transformer coupled combiner comprises:
a third secondary coil outputting a fifth radio frequency signal, the fifth radio frequency signal includes frequency components respectively at the first radio frequency and the second radio frequency; and
a fourth secondary coil outputting a sixth radio frequency signal, the sixth radio frequency signal includes frequency components respectively at the first radio frequency and the second radio frequency.

19. A substrate processing system comprising:
the radio frequency distribution circuit of claim 7;
a process chamber;
a showerhead comprising the electrode and implemented in the process chamber; and
a substrate support implemented in the process chamber adjacent the showerhead.

20. A radio frequency distribution circuit to supply radio frequency power to an electrode in a substrate processing system, the radio frequency distribution circuit comprising:
a radio frequency generator to generate a first radio frequency signal;
a transformer to convert the first radio frequency signal to a second radio frequency signal and supply the second radio frequency signal to the electrode to adjust plasma ionization density and ionization energy within a process chamber of the substrate processing system; and
a match network to match an output of the radio frequency generator to an input of the transformer.
